(19) United States
(12) Patent Application Publication
(10) Pub. No.: US 2025/0199054 A1
(43) Pub. Date: Jun. 19, 2025

(54) DEGRADATION DIAGNOSIS SYSTEM, DEGRADATION DIAGNOSIS METHOD, AND POWER CONVERTER

(71) Applicant: FUJI ELECTRIC CO., LTD., Kanagawa (JP)

(72) Inventor: Ryoga KIGUCHI, Tokyo (JP)

(21) Appl. No.: 18/958,442

(22) Filed: Nov. 25, 2024

(30) Foreign Application Priority Data
Dec. 18, 2023 (JP) 2023-213197

(51) Int. Cl. G01R 31/26; H01L 21/66; H02M 7/538

(52) U.S. Cl. CPC G01R 31/2607; H01L 22/30; H02M 7/538

(57) ABSTRACT

A degradation diagnosis system includes a semiconductor element including a gate, a first main terminal that is a source or an emitter, and a second main terminal that is a drain or a collector. The degradation diagnosis system includes a push-pull circuit, a gate resistance provided in the push-pull circuit or between the push-pull circuit and the gate, and a capacitor coupled in parallel with the gate resistance. The degradation diagnosis system includes a degradation diagnosis device configured to diagnose degradation of the semiconductor element based on a capacitor voltage that is generated across the capacitor.

### CROSS-REFERENCE TO RELATED APPLICATIONS

This application claims priority under 35 U.S.C. § 119 to Japanese Patent Application No. 2023-213197, filed Dec. 18, 2023, the contents of which are incorporated herein by reference.

### BACKGROUND

### 1. Technical Field

The present disclosure relates to a degradation diagnosis system, a degradation diagnosis method, and a power converter.

### 2. Description of the Related Art

A gate drive method for suppressing degradation of a power semiconductor by controlling a time for applying a voltage less than a source potential to a gate of the power semiconductor (for example, see Patent Document 1) is known.

### Related-Art Document

### Patent Document

Patent Document 1: Japanese Unexamined Patent Application Publication No. 2018-133892

### SUMMARY

In a conventional technique, degradation of semiconductor elements cannot be diagnosed.

The present disclosure provides a degradation diagnosis system, a degradation diagnosis method, and a power converter that are capable of diagnosing degradation of a semiconductor element.

In one aspect of the present disclosure, a degradation diagnosis system is provided. The degradation diagnosis system includes a semiconductor element including a gate, a first main terminal that is a source or an emitter, and a second main terminal that is a drain or a collector; a push-pull circuit; a gate resistance provided in the push-pull circuit or between the push-pull circuit and the gate; a capacitor coupled in parallel with the gate resistance; and a degradation diagnosis device configured to diagnose degradation of the semiconductor element based on a capacitor voltage that is generated across the capacitor.

In another aspect of the present disclosure, a degradation diagnosis method is provided. The degradation diagnosis method includes diagnosing degradation of a semiconductor element based on a capacitor voltage that is generated across a capacitor, the capacitor being coupled in parallel with a gate resistance, and the gate resistance being provided in a push-pull circuit or between the push-pull circuit and a gate of the semiconductor element.

In another aspect of the present disclosure, a power converter is provided. The power converter includes a semiconductor element including a gate, a first main terminal that is a source or an emitter, and a second main terminal that is a drain or a collector; a push-pull circuit; a gate resistance provided in the push-pull circuit or between the push-pull circuit and the gate; a capacitor coupled in parallel with the gate resistance; a degradation diagnosis device configured to diagnose degradation of the semiconductor element based on a capacitor voltage that is generated across the capacitor; and a peak hold circuit configured to hold a maximum value of a capacitor voltage during a predetermined time period, in an operating cycle of the semiconductor element.

In the present disclosure, degradation of a semiconductor element can be diagnosed.

### BRIEF DESCRIPTION OF THE DRAWINGS

FIG. 1 is a diagram showing a configuration example of a degradation diagnosis system according to a first embodiment.

FIG. 2 is a diagram for describing the degradation of a semiconductor element.

FIG. 3 is a diagram for describing a method for diagnosing the degradation of the semiconductor element.

FIG. 4 is a diagram for describing the method for diagnosing the degradation of a semiconductor element.

FIG. 5 is a diagram showing a configuration example of the degradation diagnosis system according to a second embodiment.

FIG. 6 is a timing chart for describing a first example of a method for sampling a maximum value of a capacitor voltage over a predetermined time period, in an operating cycle of the semiconductor element.

FIG. 7 is a timing chart for describing a second example of the method for sampling the maximum value of the capacitor voltage over the predetermined time period, in the operating cycle of the semiconductor element.

FIG. 8 is a timing chart for describing a third example of the method for sampling the maximum value of the capacitor voltage over the predetermined time period, in the operating cycle of the semiconductor element.

FIG. 9 is a diagram showing a configuration example of the degradation diagnosis system according to a third embodiment.

FIG. 10 is a diagram showing a configuration example of the degradation diagnosis system according to a fourth embodiment.

FIG. 11 is a diagram showing a configuration example of the degradation diagnosis system according to a fifth embodiment.

FIG. 12 is a diagram showing a configuration example of the degradation diagnosis system according to a sixth embodiment.

FIG. 13 is a diagram showing a first example of application of the degradation diagnosis system to a power converter according to the present embodiment.

FIG. 14 is a diagram showing a second example of application of the degradation diagnosis system to the power converter according to the present embodiment.

### DETAILED DESCRIPTION

Embodiments of the present disclosure will be described below.

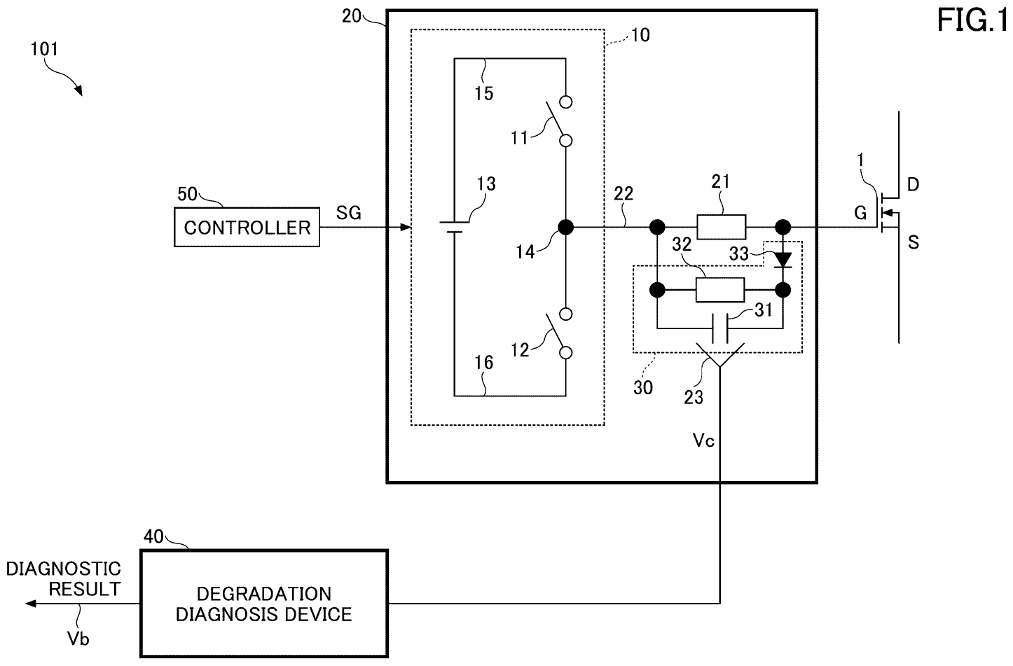

FIG. 1 is a diagram showing a configuration example of a degradation diagnosis system according to a first embodiment. A degradation diagnosis system 101 shown in FIG. 1 is a system for diagnosing degradation of a semiconductor element 1 (for example, a gate oxide film or bulk of the semiconductor element 1). The degradation diagnosis system 101 includes the semiconductor element 1, a gate drive circuit 20, and a degradation diagnosis device 40. The degradation diagnosis system 101 may include a controller 50 as a component. The gate drive circuit 20 includes, for example, a push-pull circuit 10, a gate line 22, a gate resistance 21, a speed-up capacitor circuit 30, and a detection circuit 23.

The semiconductor element 1 is a switching element that is driven by the gate drive circuit 20. The semiconductor element 1 includes a gate, a first main terminal that is a source or an emitter, and a second main terminal that is a drain or a collector. FIG. 1 illustrates a case where the semiconductor element 1 is a metal oxide semiconductor field effect transistor (MOSFET) including a gate G, a source S, and a drain D. As another example of the semiconductor element 1, an insulated gate bipolar transistor (IGBT) or the like is used.

The controller 50 is a controller that generates one or more control signals SG for driving the push-pull circuit 10. The controller 50 may be implemented by (i) an analog circuit that is constituted by a combination of logic circuits, (ii) a computer including a processor and a memory, or (iii) a combination of the analog circuit and the computer. The controller 50 may be configured by one unit or may be configured by a plurality of separate units.

The push-pull circuit 10 is a drive unit that drives the gate G of the semiconductor element 1 in accordance with a control signal SG that is supplied from the controller 50. The push-pull circuit 10 includes a first power line 15, a second power line 16, a power supply 13, a first switch 11, a second switch 12, and a connection point 14.

The first power line 15 is a positive power line that outputs a positive power voltage for maintaining the semiconductor element 1 in an on state. The first power line 15 is connected to the power supply 13 that generates the positive power voltage. The second power line 16 is a negative power line that outputs a negative power voltage for maintaining the semiconductor element 1 in an off state. The second power line 16 is connected to the power supply 13 that generates the negative power voltage. The second power line 16 may be a ground line that outputs a ground voltage for maintaining the semiconductor element 1 in the off state.

The first switch 11 is a switching unit that controls the connection between the gate line 22, which is connected to the connection point 14, and the first power line 15 in accordance with the control signal SG generated by the controller 50. The first switch 11 is a circuit or an element that is turned on or off in accordance with the control signal SG. When the first switch 11 is turned on, the gate line 22 and the first power line 15 are electrically connected to each other. When the first switch 11 is turned off, the gate line 22 and the first power line 15 are electrically disconnected from each other.

The second switch 12 is a switching unit that controls the connection between the gate line 22, which is connected to the connection point 14, and the second power line 16 in accordance with the control signal SG generated by the controller 50. The second switch 12 is a circuit or an element that is turned on or off in accordance with the control signal SG. When the second switch 12 is turned on, the gate line 22 and the second power line 16 are electrically connected to each other, and when the second switch 12 is turned off, the gate line 22 and the second power line 16 are electrically disconnected from each other.

The push-pull circuit 10 alternately switches the first switch 11 and the second switch 12 on or off according to the control signal SG, with a dead time during which both the first switch 11 and the second switch 12 are off. When the first switch 11 is on and the second switch 12 is off, the semiconductor element 1 is turned on because the positive power voltage is applied between the gate G and the source S of the semiconductor element 1. When the first switch 11 is off and the second switch 12 is on, the semiconductor element 1 is turned off because the negative power voltage is applied between the gate G and the source S of the semiconductor element 1.

The gate line 22 is a drive line that connects the connection point 14 of the push-pull circuit 10 to the gate G of the semiconductor element 1. The gate resistance 21 is a resistive element provided between the connection point 14 of the push-pull circuit 10 and the gate G of the semiconductor element 1. The gate resistance 21 is inserted in series in the gate line 22.

The speed-up capacitor circuit 30 is a circuit for reducing the turn-off time of the semiconductor element 1. The speed-up capacitor circuit 30 is connected in parallel with the gate resistance 21. The speed-up capacitor circuit 30 includes a capacitor 31 connected in parallel with the gate resistance 21, a discharge resistor 32 connected in parallel with the capacitor 31, and a diode 33 inserted in series in a path along which a charge is transferred from the gate G to the capacitor 31. In this example, in the diode 33, an anode is connected to the gate line 22 between the gate resistance 21 and the gate G, and a cathode is connected to respective ends of the capacitor 31 and the discharge resistor 32.

When the second switch 12 switches from off to on, the charge that is stored in the gate G of the semiconductor element 1 moves to the capacitor 31 via the diode 33. As a result, a voltage Vgs between the gate G and the source S of the semiconductor element 1 quickly decreases, thereby reducing the turn-off time of the semiconductor element 1. As the voltage Vgs of the semiconductor element 1 decreases, a voltage (capacitor voltage Vc) generated across the capacitor 31 increases. When the capacitor voltage Vc becomes equal to the voltage Vgs, the charge accumulated in the capacitor 31 starts discharging through the discharge resistor 32. Thus, even if the turn-off time of the semiconductor element 1 is reduced, the discharge of the capacitor 31 can be started during a turn-off process of the semiconductor element 1.

The detection circuit 23 detects the voltage (capacitor voltage Vc) generated across the capacitor 31, and outputs a detection value of the capacitor voltage Vc.

The degradation diagnosis device 40 diagnoses the degradation of the semiconductor element 1 based on the detection value of the capacitor voltage Vc detected by the detection circuit 23. The degradation diagnosis device 40 outputs a signal Vb representing a diagnosis result of the degradation of the semiconductor element 1.

The degradation diagnosis device 40 may be implemented by an analog circuit that is constituted by a combination of logic circuits; a computer including a processor and a memory; or a combination of the analog circuit and the computer. A function of the degradation diagnosis device 40 (a process performed by the degradation diagnosis device 40) is realized by operating a processor such as a central processing unit (CPU) by a program stored in a memory, for example. The function of the degradation diagnosis device 40 may be realized by a field programmable gate array (FPGA) or an application specific integrated circuit (ASIC).

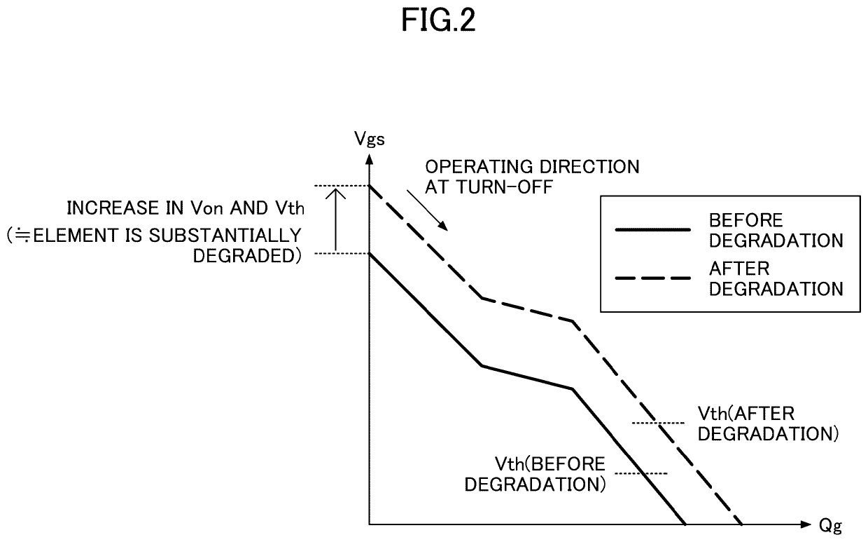

FIG. 2 is a diagram for describing the degradation of the semiconductor element. The horizontal axis represents an amount of charge Qg discharged from the gate G at the turn-off of the semiconductor element 1. The vertical axis represents the voltage Vgs between the gate G and the source S, during the turn-off of the semiconductor element 1. A Qg-Vgs curve represents a gate dynamic characteristic of the semiconductor element 1.

When the semiconductor element 1 (particularly, a gate oxide film of the semiconductor element 1) degrades, an on-voltage Von (the voltage between the drain D and the source S in an on state) and a threshold voltage Vth for the semiconductor element 1 vary. Depending on a device structure, as the degradation of the semiconductor element 1 progresses, the Qg-Vgs curve shifts as shown in FIG. 2, and thus each of the on-voltage Von and the threshold voltage Vth is increased. The increase in each of the on-voltage Von and the threshold voltage Vth may result in an increase in heat generation of the semiconductor element 1. As a result, degradation of the semiconductor element 1 may rise concerns in terms of power cycling reliability.

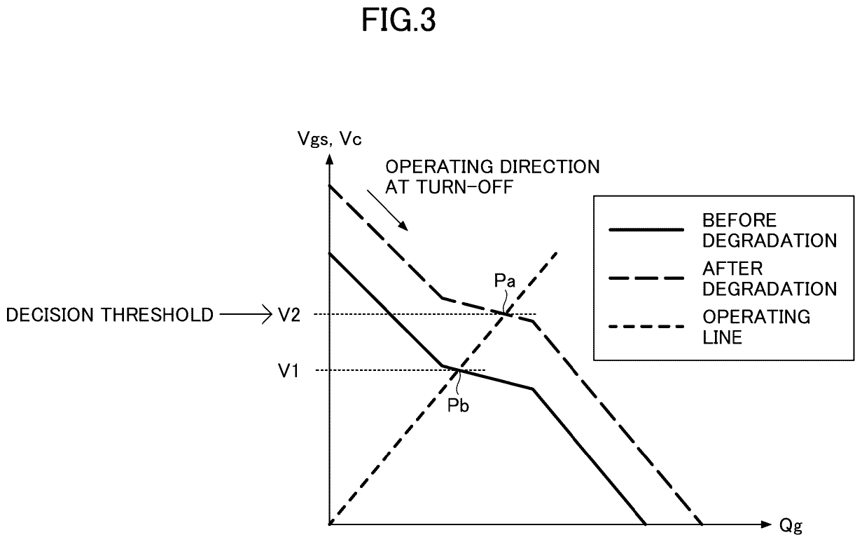

FIG. 3 is a diagram for describing a method for diagnosing the degradation of the semiconductor element. In FIG. 3, an operating line for the capacitor voltage Vc generated across the capacitor 31 is added to the characteristic diagram shown in FIG. 2. The capacitor voltage Vc is determined by gate capacitance and a gate charge for the semiconductor element 1; and capacitance and the charge for the capacitor 31. With this approach, with use of “Vgs=Qg/(capacitance of the capacitor 31),” the operating line for the capacitor 31 on a Qg-Vgs plane is represented by a straight line with a slope that is equal to an inverse of the capacitance of the capacitor 31. In FIG. 3, intersection points Pa and Pb of the operating line for the capacitor 31 and the Qg-Vgs curve express operating points at which the capacitor voltage Vc becomes equal to the voltage Vgs.

As shown in FIG. 3, voltage values obtained when the capacitor voltage Vc becomes equal to the voltage Vgs differ from each other, before and after the degradation of the semiconductor element 1. A voltage value V1 is a voltage value when the capacitor voltage Vc becomes equal to the voltage Vgs of the semiconductor element 1, before degradation. A voltage value V2 is a voltage value when the capacitor voltage Vc becomes equal to the voltage Vgs of the semiconductor element 1, after degradation. The degradation diagnosis device 40 according to the first embodiment diagnoses the degradation of the semiconductor element 1 by observing a difference between the voltage value V1 and the voltage value V2. For example, when the value of the capacitor voltage Vc that is detected during a switching operation of the semiconductor element 1 (in this example, during turn-off) is greater than the voltage value V2 that is set as a decision threshold, the degradation diagnosis device 40 diagnoses that the semiconductor element 1 is degraded.

In this arrangement, the degradation diagnosis device 40 according to the first embodiment can diagnose the degradation of the semiconductor element 1 by using the capacitor voltage Vc. By detecting the capacitor voltage Vc, the degradation diagnosis device 40 improves noise resistance as compared with a case where the degradation is diagnosed by directly measuring a change in the voltage Vgs due to the degradation. This is because the capacitor 31 provides effects of filtering a voltage waveform. In addition, in the degradation diagnosis device 40, the capacitor voltage Vc detected during the switching operation of the semiconductor element 1 is used for the degradation diagnosis of the semiconductor element 1, and as a result, the degradation of the semiconductor element 1 can be diagnosed without stopping a device (for example, a power converter) that uses the semiconductor element 1.

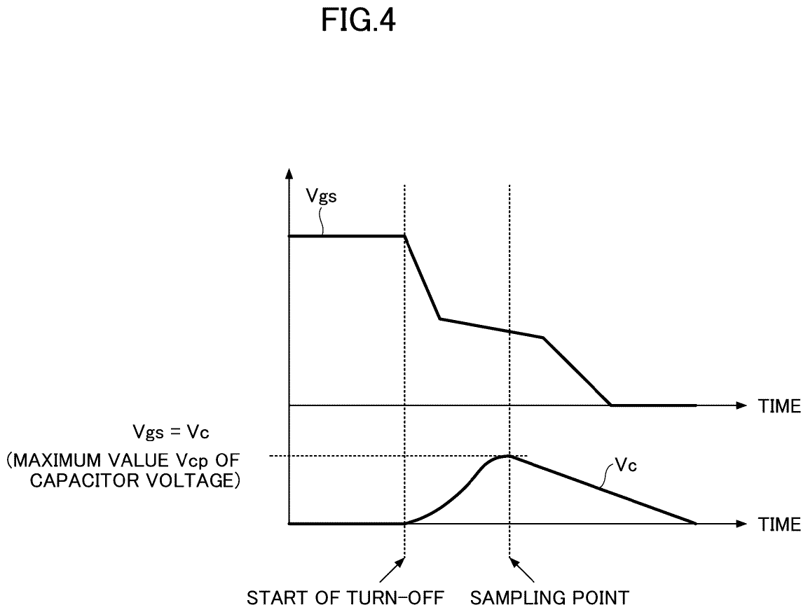

FIG. 4 is a diagram for describing the method for diagnosing the degradation of the semiconductor element. FIG. 4 is a timing chart obtained based on the characteristic diagram shown in FIG. 3. The horizontal axis represents the time. The vertical axis represents the voltage Vgs and the capacitor voltage Vc when the semiconductor element 1 is turned off.

As shown in FIG. 4, during the switching operation (in this example, during turn-off) of the semiconductor element 1, the capacitor voltage Vc becomes equal to the voltage Vgs at a timing at which the capacitor voltage Vc reaches a maximum value Vcp (local maximum). In this case, the degradation diagnosis device 40 can diagnose the degradation of the semiconductor element 1 by using the maximum value Vcp of the capacitor voltage Vc. For example, when the maximum value Vcp of the capacitor voltage Vc that is detected during the switching operation of the semiconductor element 1 exceeds the voltage value V2 (see FIG. 3) set as the decision threshold, the degradation diagnosis device 40 diagnoses that the semiconductor element 1 is degraded.

The maximum value Vcp of the capacitor voltage Vc during the switching operation of the semiconductor element 1 is easily detected by peak-holding the capacitor voltage Vc. Hereinafter, a degradation diagnosis system having a peak hold function of the capacitor voltage Vc will be described.

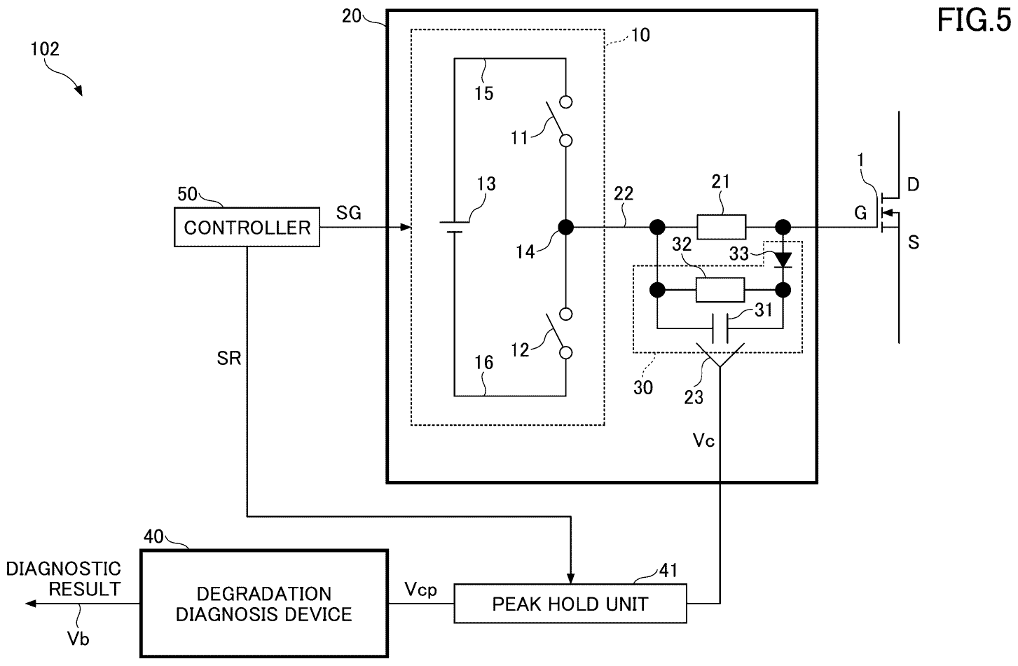

FIG. 5 is a diagram showing a configuration example of the degradation diagnosis system according to a second embodiment. In the second embodiment, description of the same configuration, operation, and effect as described in the above embodiment will be omitted by referring to the above-described description. A degradation diagnosis system 102 according to the second embodiment shown in FIG. 5 differs from the above-described degradation diagnosis system 101 in that the degradation diagnosis system 102 has the peak hold function of the capacitor voltage Vc.

The degradation diagnosis system 102 includes a peak hold unit 41 having a function of holding the maximum value Vcp of the capacitor voltage Vc during a predetermined time period T. The peak hold unit 41 can accurately sample the maximum value Vcp of the capacitor voltage Vc during the predetermined time period T. The peak hold unit 41 may be configured in the gate drive circuit 20 or the degradation diagnosis device 40.

For example, the peak hold unit 41 samples the maximum value Vcp of the capacitor voltage Vc during the predetermined time period T, in accordance with a reset signal SR that is synchronized with the operating cycle of the semiconductor element 1. As a result, the degradation diagnosis device 40 can acquire the maximum value Vcp of the capacitor voltage Vc during the predetermined time period T, for each operating cycle of the semiconductor element 1. In this arrangement, the degradation diagnosis device 40 can update a degradation diagnosis result for the semiconductor element 1, for each operating cycle of the semiconductor element 1.

The reset signal SR is generated, for example, by the controller 50 that controls the operation of the semiconductor element 1. However, the reset signal SR may be a signal that the gate drive circuit 20 generates based on the control signal SG.

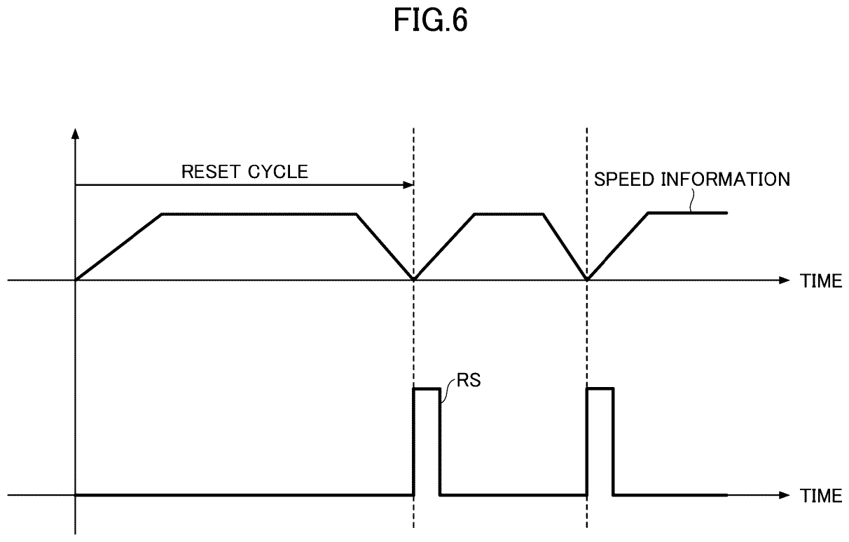

FIG. 6 is a timing chart for describing a first example of a method for sampling the maximum value of the capacitor voltage during the predetermined time period, according to the operating cycle of the semiconductor element. The peak hold unit 41 samples the maximum value Vcp of the capacitor voltage Vc during the predetermined time period T, according to the reset signal SR that is synchronized with the operating cycle of the semiconductor element 1.

The upper part of FIG. 6 shows a first example of the operating cycle of the semiconductor element 1. As an example of a device including the semiconductor element 1, a power converter for operating a load such as a motor driven by the semiconductor element 1, in an operating cycle that repeatedly follows the sequence of an acceleration, a constant speed, a deceleration, and a stop. The power converter has, for example, the configuration shown in FIG. 5. In FIG. 6, the controller 50 outputs both the control signal SG to turn off the semiconductor element 1 and the reset signal SR to sample and reset the maximum value Vcp in synchronization with a timing at which a load of the motor or the like is stopped. Each time the reset signal SR is input to the peak hold unit 41, the peak hold unit 41 samples the maximum value Vcp of the capacitor voltage Vc that is detected during the turn-off of the semiconductor element 1. As a result, the degradation diagnosis device 40 acquires the maximum value Vcp of the capacitor voltage Vc during the predetermined time period T, every time the semiconductor element 1 stops. As a result, the degradation diagnosis device 40 updates a degradation diagnosis result for the semiconductor element 1, every time the semiconductor element 1 is stopped.

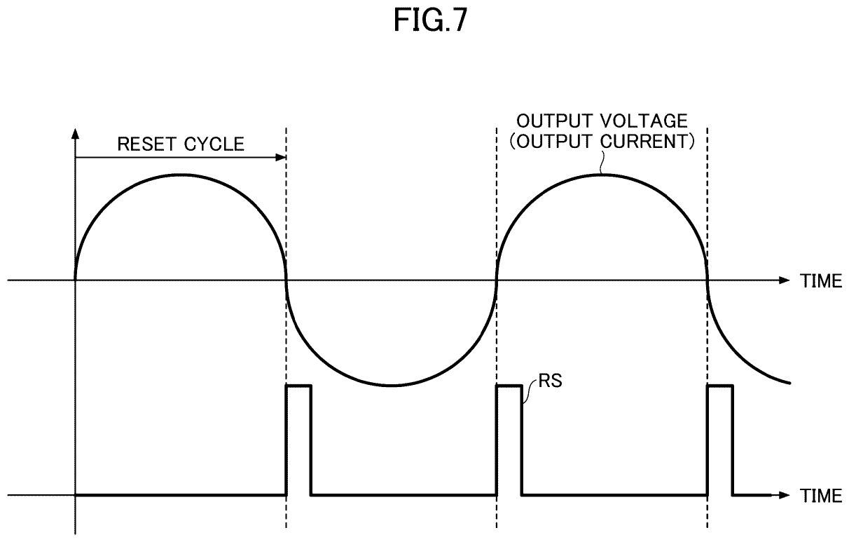

FIG. 7 is a timing chart for describing a second example of the method for sampling the maximum value of the capacitor voltage during the predetermined time period according to the operating cycle of the semiconductor element. The peak hold unit 41 samples the maximum value Vcp of the capacitor voltage Vc during a predetermined time period T, according to the reset signal SR synchronized with the operating cycle of the semiconductor element 1.

The upper part of FIG. 7 shows a second example of the operating cycle of the semiconductor element 1. An example of a device including the semiconductor element 1 is a constant voltage constant frequency (CVCF) power supply that supplies a voltage having a constant frequency to a load. The CVCF power supply is an example of a power converter, and has, for example, the configuration shown in FIG. 5. In FIG. 7, the controller 50 outputs the reset signal SR to reset by sampling the maximum value Vcp in synchronization with a timing at which an output voltage or an output current, having a constant frequency, supplied to the load crosses zero. Each time the reset signal SR is input to the peak hold unit 41, the peak hold unit 41 samples the maximum value Vcp of the capacitor voltage Vc that is detected during the turn-off of the semiconductor element 1. In this arrangement, the degradation diagnosis device 40 acquires the maximum value Vcp of the capacitor voltage Vc in a predetermined time period T, at each zero-crossing of the output voltage or the output current of the semiconductor element 1. Also, the degradation diagnosis device 40 updates a degradation diagnosis result for the semiconductor element 1, at each zero-crossing of the output voltage or the output current of the semiconductor element 1.

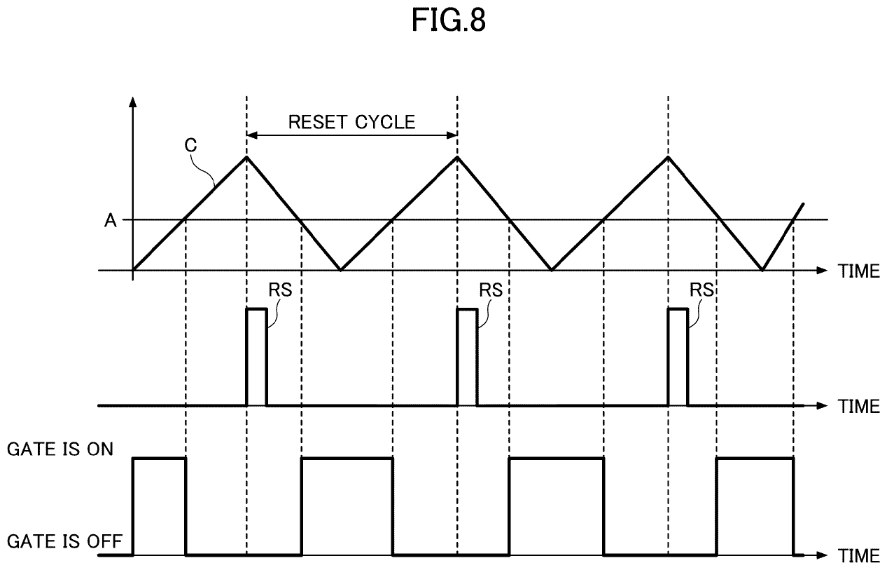

FIG. 8 is a timing chart for describing a third example of the method for sampling the maximum value of the capacitor voltage over a predetermined time period, according to the operating cycle of the semiconductor element. The peak hold unit 41 samples the maximum value Vcp of the capacitor voltage Vc over a predetermined time period T, according to the reset signal SR synchronized with the operating cycle of the semiconductor element 1.

The upper part of FIG. 8 shows a third example of the operating cycle of the semiconductor element 1. Specifically, the upper part of FIG. 8 shows a carrier cycle (a cycle of the carrier C) for driving the gate of the semiconductor element 1. The carrier cycle represents a pulse width modulation cycle for driving the semiconductor element 1 by pulse width modulation. The controller 50 samples the maximum value Vcp in synchronization with the carrier cycle, and outputs a reset signal SR for resetting. Each time the reset signal SR is input to the peak hold unit 41, the peak hold unit 41 samples the maximum value Vcp of the capacitor voltage Vc that is detected during the turn-off of the semiconductor element 1. As a result, the degradation diagnosis device 40 acquires the maximum value Vcp of the capacitor voltage Vc during a predetermined time period T, in each carrier cycle of the semiconductor element 1. As a result, the degradation diagnosis device 40 updates a degradation diagnosis result for the semiconductor element 1, in each carrier cycle of the semiconductor element 1.

The controller 50 turns the semiconductor element 1 on or off by comparing a carrier C with a command value A. For example, the controller 50 outputs a gate-off command for the semiconductor element 1 when the carrier C is greater than the command value A. When the controller 50 outputs the reset signal SR at a timing at which the carrier C has a maximum value or a minimum value (in this example, the maximum value), the semiconductor element 1 can be reliably reset in an off state of the gate.

It is sufficient when the maximum value Vcp is sampled after the semiconductor element 1 is completely turned off and before the reset signal SR is input. That is, a timing at which the maximum value Vcp is sampled does not necessarily need to be the same as a timing at which the reset signal SR is input to the peak hold unit 41.

The turn-off completion of the semiconductor element 1 may be determined by factors such as (i) a voltage applied between the gate G and the source S of the semiconductor element 1, (ii) a voltage applied between the drain D and the source S of the semiconductor element 1, (iii) a current flowing through the drain D, or (iv) an elapsed time after a turn-off signal is input to the semiconductor element 1. The turn-off completion of the semiconductor element 1 may be determined by information on the above factors for a semiconductor element (not shown) that is connected in series with the semiconductor element 1.

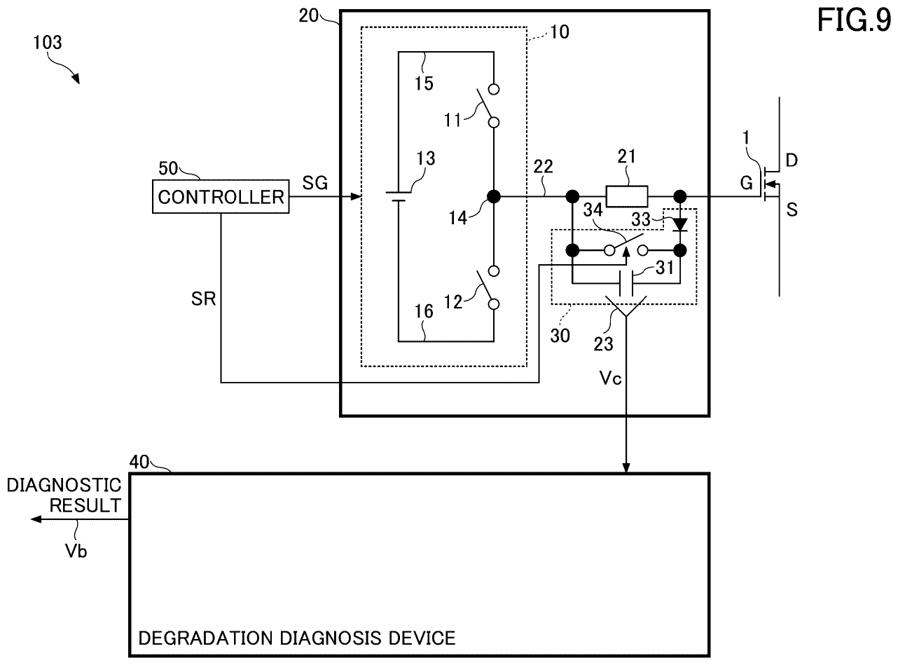

FIG. 9 is a diagram showing a configuration example that embodies the method shown in FIG. 8. In FIG. 9, description of the same configuration, operation, and effect as described in the above embodiments will be omitted by referring to the above description. A degradation diagnosis system 103 according to a third embodiment shown in FIG. 9 differs from the above degradation diagnosis systems 101 and 102 in that the degradation diagnosis system 103 includes a reset circuit 34.

The reset circuit 34 includes a reset switch connected in parallel to the capacitor 31. The reset circuit 34 discharges the charge of the capacitor 31 by turning on the reset switch in accordance with the reset signal SR that is synchronized with the operating cycle of the semiconductor element 1. In this arrangement, the capacitor 31 can be discharged for each carrier cycle, without using the discharge resistor 32.

When the second switch 12 switches from off to on, the charge accumulated in the gate G of the semiconductor element 1 moves to the capacitor 31 through the diode 33 without moving to the reset circuit 34 in which the reset switch is off. As a result, the voltage Vgs between the gate G and the source S of the semiconductor element 1 quickly decreases, and thus the turn-off time of the semiconductor element 1 is reduced. As the voltage Vgs of the semiconductor element 1 decreases, the voltage (capacitor voltage Vc) generated across the capacitor 31 increases. The reset circuit 34 switches the reset switch from off to on when the reset signal SR synchronized with the operating cycle of the semiconductor element 1 is input. When the reset switch is turned on, the charge accumulated in the capacitor 31 starts to discharge through the reset switch that is held in an on state. Thus, even if the turn-off time of the semiconductor element 1 is reduced, the discharge of the capacitor 31 can be started during a turn-off process of the semiconductor element 1.

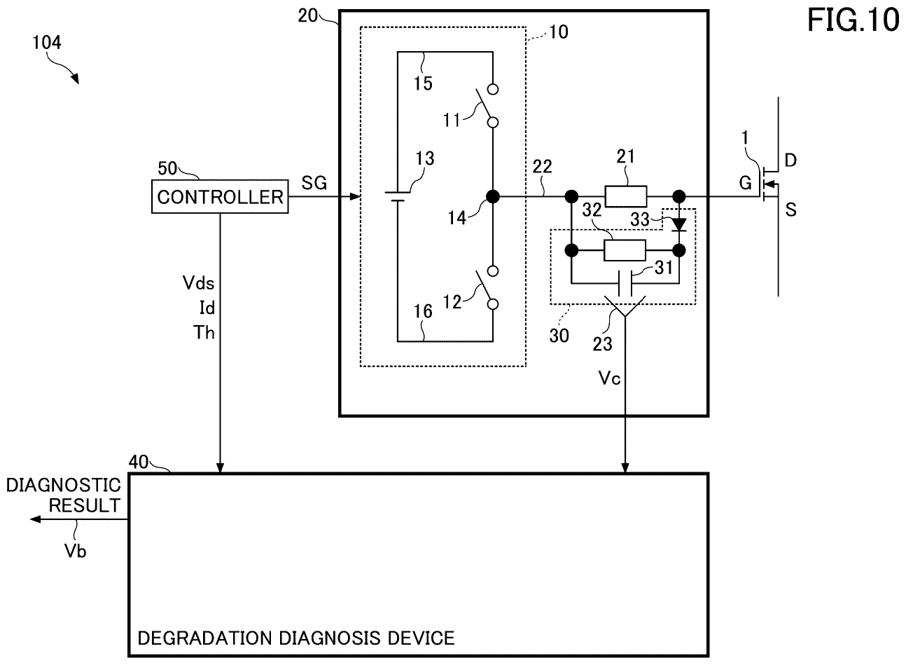

FIG. 10 is a diagram showing a configuration example of the degradation diagnosis system according to a fourth embodiment. In the fourth embodiment, description of the same configuration, operation, and effect as described in the above embodiments will be omitted by referring to the above description. A degradation diagnosis system 104 according to the fourth embodiment shown in FIG. 10 differs from the above-described degradation diagnosis system 101 or the like in that the degradation diagnosis device 40 diagnoses the degradation of the semiconductor element 1 by using the capacitor voltage Vc and information related to the semiconductor element 1.

Examples of the information related to the semiconductor element 1 include the voltage Vds between the drain D and the source S of the semiconductor element 1, the current Id flowing between the drain D and the source S of the semiconductor element 1, the temperature Th of the semiconductor element 1, and the like.

The information related to the semiconductor element 1, such as the voltage Vds, the current Id, or the temperature Th, is measured by a known technique that includes a sensor or the like, for example. The degradation diagnosis device 40 may acquire the information related to the semiconductor element 1, from the controller 50, the gate drive circuit 20, or any other device.

The Qg-Vgs curve (see FIG. 2) changes according to the voltage Vds, the current Id, or the temperature Th. With reference to FIG. 2, as the voltage Vds or the current Id increases, or as the temperature Th decreases, the Qg-Vgs curve shifts as shown in FIG. 2. As a result, the on-voltage Von and the threshold voltage Vth are increased. Therefore, when the degradation diagnosis device 40 uses the information related to the semiconductor element 1 for the degradation diagnosis of the semiconductor element 1, accuracy in diagnosing degradation of the semiconductor element 1 is improved.

The degradation diagnosis device 40 may diagnose the degradation of the semiconductor element 1 when the information related to the semiconductor element 1, such as the voltage Vds, the current Id, or the temperature Th, satisfies a predetermined condition. Thus, a timing at which the degradation of the semiconductor element 1 is diagnosed is limited when the information of the semiconductor element 1 such as the voltage Vds, the current Id, or the temperature Th satisfies a predetermined condition. For example, a frequency of diagnosing the degradation of the semiconductor element 1 is suppressed without becoming excessive.

As a case example where the predetermined condition is satisfied, at least one of a first condition in which the voltage Vds is greater than a predetermined voltage threshold; a second condition in which the current Id is greater than a predetermined current threshold; or a third condition in which the temperature is lower than a predetermined temperature threshold, is satisfied.

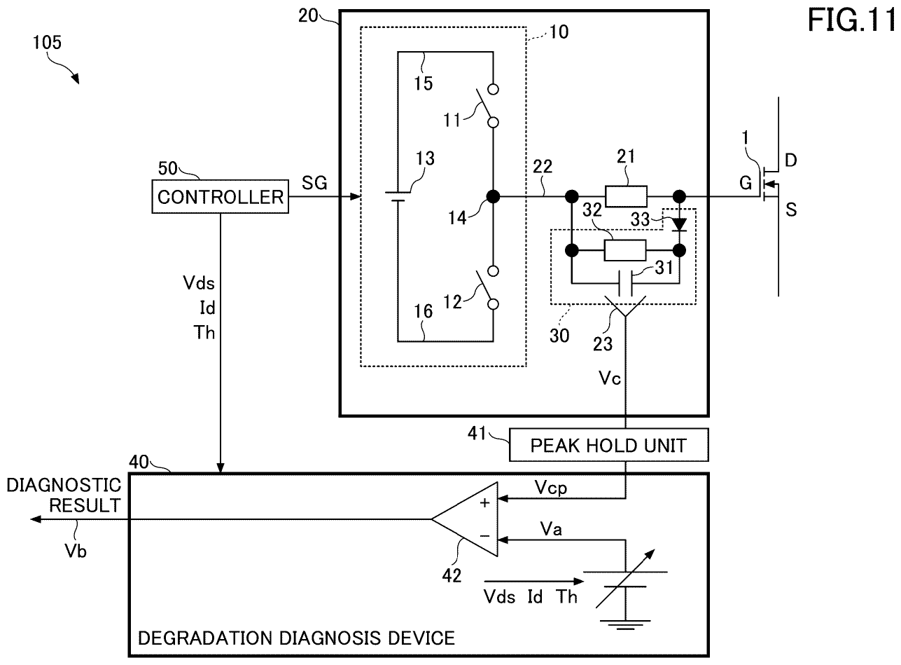

FIG. 11 is a diagram showing a configuration example of the degradation diagnosis system according to a fifth embodiment. In the fifth embodiment, the description of the configuration, operation, and effect similar to the above limitation is limited to those of the above embodiments is omitted by referring to the above description. The degradation diagnosis system 105 according to the fifth embodiment shown in FIG. 11 is different from the above-described degradation diagnosis system 101 and the like in that the degradation diagnosis device 40 diagnoses the degradation of the semiconductor element 1 by comparing the capacitor voltage Vc with a threshold value that is set according to the information related to the semiconductor element 1.

The degradation diagnosis device 40 sets a threshold Va corresponding to the information related to the semiconductor element 1 that is acquired by the controller 50 or the like, based on the relationship between the information related to the semiconductor element 1 such as the voltage Vds, the current Id, or the temperature Th, and the threshold Va. In this arrangement, the degradation diagnosis device 40 can set the threshold Va suitable for the acquired information related to the semiconductor element 1. The threshold Va is a decision threshold for diagnosing the degradation of the semiconductor element 1, and corresponds, for example, to a voltage value V2 (see FIG. 3). The relationship between the information related to the semiconductor element 1 and the threshold Va is determined by a map or an arithmetic formula. The degradation diagnosis device 40 diagnoses the degradation of the semiconductor element 1 by comparing the maximum value Vcp of the capacitor voltage Vc with the threshold Va using the comparator 42. For example, the degradation diagnosis device 40 diagnoses that the semiconductor element 1 is degraded when the maximum value Vcp is greater than the threshold Va.

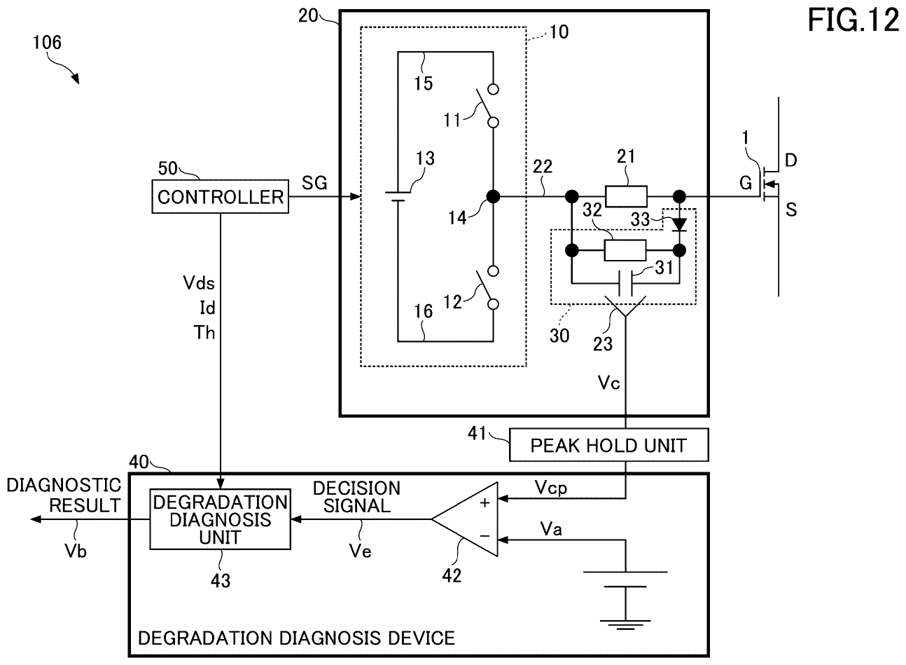

FIG. 12 is a diagram showing a configuration example of the degradation diagnosis system according to a sixth embodiment. In the sixth embodiment, description of the same configuration, operation, and effect as described in the above embodiments will be omitted by referring to the above description. A degradation diagnosis system 106 according to the sixth embodiment shown in FIG. 12 differs from the degradation diagnosis system 105 described above in that the degradation diagnosis device 40 diagnoses the degradation of the semiconductor element 1 by comparing the capacitor voltage Vc with a constant threshold Va.

The degradation diagnosis device 40 diagnoses the degradation of the semiconductor element 1 by the degradation diagnosis unit 43, using the information (e.g., the voltage Vds, the current Id, or the temperature Th, or like) related to the semiconductor element 1 when the maximum value Vcp of the capacitor voltage Vc is greater than the constant threshold Va. Since the degradation diagnosis unit 43 for diagnosing the degradation does not read a detection value of the capacitor voltage Vc itself, the number of AD converters that detect the capacitor voltage Vc can be reduced.

For example, the threshold Va may be stored in a memory in advance, or may be provided as a voltage source having a voltage of the threshold Va. The threshold Va is determined by a test performed in advance or a data sheet.

The degradation diagnosis device 40 may diagnose the degradation of the semiconductor element 1 when the information related to the semiconductor element 1 satisfies a predetermined condition, and the capacitor voltage Vc is greater than a constant threshold Va. For example, the degradation diagnosis device 40 compares the maximum value Vcp of the capacitor voltage Vc with the threshold Va by the comparator 42, and asserts the decision signal Ve when the maximum value Vcp is greater than the threshold Va. The degradation diagnosis unit 43 may diagnose that the semiconductor element 1 is degraded when the information related to the semiconductor element 1, such as the voltage Vds, the current Id, or the temperature Th, satisfies the predetermined conditions, and the decision signal Ve is asserted. The degradation diagnosis unit 43 receives the decision signal Ve and acquires the information of the semiconductor element 1 such as the voltage Vds, the current Id, or the temperature Th, and may diagnose that the semiconductor element 1 is deteriorated when the information satisfies the predetermined conditions.

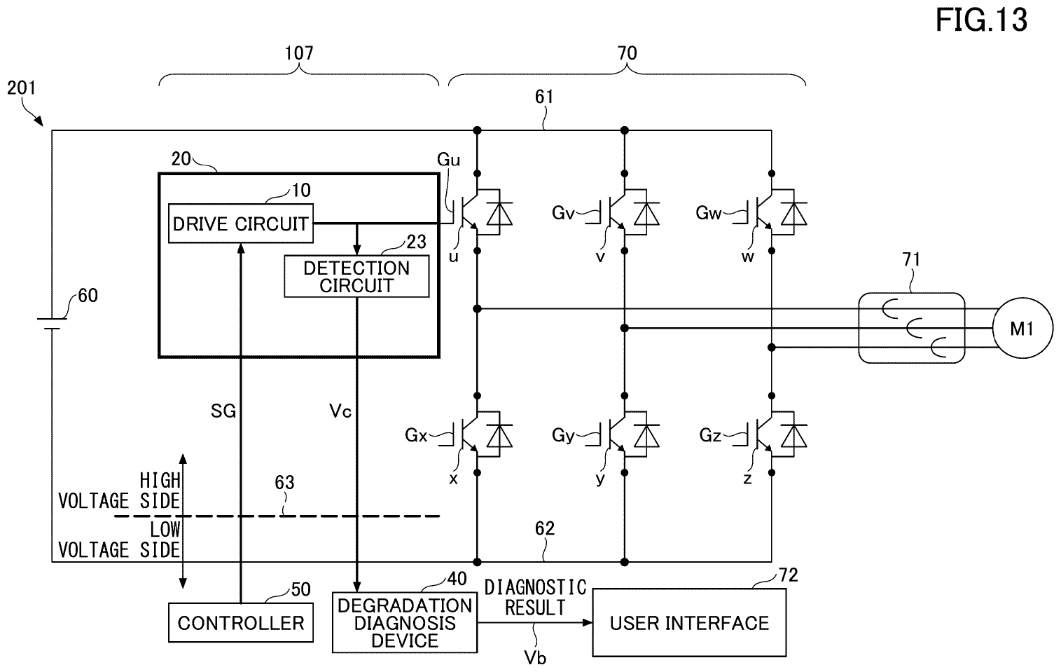

FIG. 13 is a diagram showing a first example of application of the degradation diagnosis system according to the present embodiment to a power converter. A degradation diagnosis system 107 shown in FIG. 13 may be any one of a plurality of degradation diagnosis systems of the present disclosure. A power converter 201 includes an inverter circuit 70 that converts direct current (DC) power that is input from the DC power supply 60, into alternating current (AC) power, and supplies the AC power to a load Ml, such as a motor. The current sensor 71 detects an AC current flowing between the inverter circuit 70 and the load Ml, and outputs a detection value of the AC current to the controller 50 and the degradation diagnosis device 40. The controller 50 generates the control signal SG for driving the inverter circuit 70, using the detection value of the AC current detected by the current sensor 71.

The inverter circuit 70 is a bridge circuit that is configured by a plurality of semiconductor elements u, v, w, x, y, z that are connected between a first DC bus 61 and a second DC bus 62. The inverter circuit 70 converts the DC voltage input from the DC power supply 60 into an AC voltage by switching the plurality of semiconductor elements u, v, w, x, y, and z, and the drives the load Ml of a motor or the like with three-phase AC.

The controller 50 generates a plurality of control signals SG for driving gates Gu, Gv, Gw, Gx, Gy, and Gz of the plurality of semiconductor elements u, v, w, x, y, and z, such that a three-phase alternating current (AC) generated through the inverter circuit 70 flows into the load Ml.

Each of the semiconductor elements u, v, w, x, y, and z is an example of the semiconductor element 1 described above. FIG. 13 illustrates a case where the semiconductor element 1 is an insulated gate bipolar transistor (IGBT) including a gate G, an emitter, and a collector.

The degradation diagnosis device 40 acquires the capacitor voltage Vc that is detected by an isolated AD converter, through the insulation 63 that insulates between a high potential side and a low potential side. Although not shown, the degradation diagnosis device 40 acquires information related to the semiconductor element 1, such as the voltage Vds, the current Id, or the temperature Th, by using the low potential side such as the controller 50.

The degradation diagnosis device 40 is provided in an external device (for example, the controller 50 or an external server (not shown)) having relatively high computational capacity. By providing the degradation diagnosis device 40 in the external device having the high computational capacity, degradation of the semiconductor element can be diagnosed with high accuracy.

The degradation diagnosis device 40 diagnoses the degradation of a part or all of the plurality of semiconductor elements u, v, w, x, y, and z. In this description, the degradation diagnosis device 40 diagnoses the degradation of a semiconductor element u as a representative case. The degradation diagnosis device 40 transmits a diagnostic result of the degradation of a part or all of the plurality of semiconductor elements u, v, w, x, y, and z, to the user interface 72. The user interface 72 presents the received diagnostic result to a user, through at least one of a screen display, a lamp, or a speaker. With this approach, the user can recognize the diagnostic result.

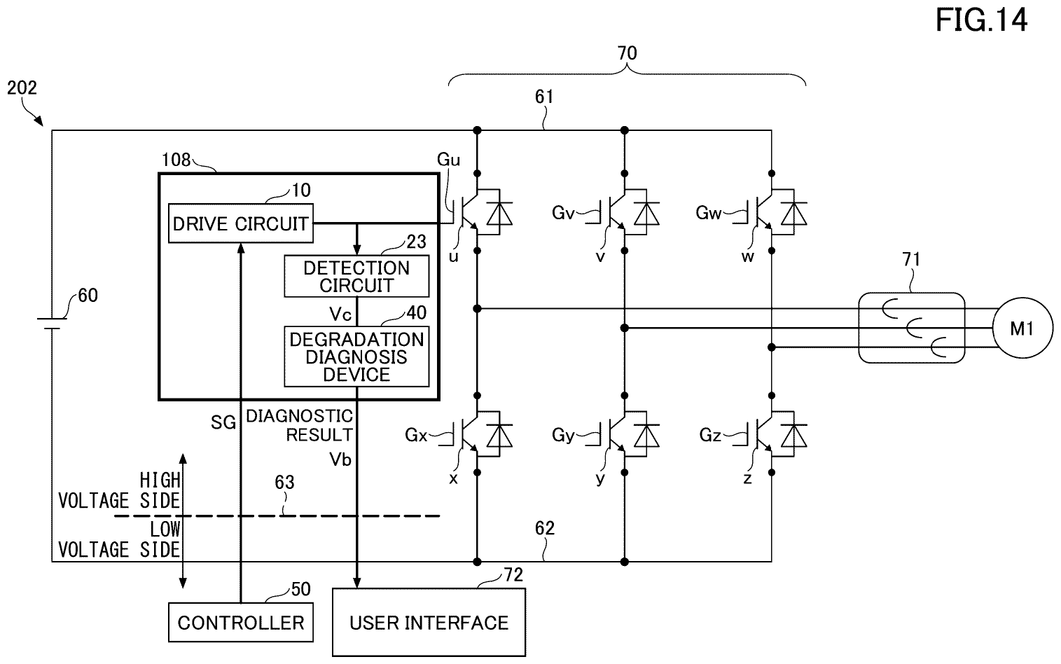

FIG. 14 is a diagram showing a second example of application of the degradation diagnosis system according to the present embodiment to the power converter. A degradation diagnosis system 108 shown in FIG. 14 may be any one of the plurality of degradation diagnosis systems of the present disclosure. A configuration related to a power conversion operation of the power converter 202 shown in FIG. 14 may be the same as that of the power converter 201 described above. In the present embodiment, the information related to the semiconductor element 1, such as the voltage Vds, the current Id, or the temperature Th, may be acquired from the high potential side.

The degradation diagnosis device 40 is provided in a power converter 202 (e.g., a gate drive circuit). By a wired or wireless connection, the degradation diagnosis device 40 transmits a diagnosis result for the semiconductor element to the user interface 72 that is provided outside the power converter 202. The diagnosis result transmitted from the degradation diagnosis device 40 of the gate drive circuit, which is provided on the high potential side, to the user interface 72 provided on the low potential side, is information having a relatively small amount of information (for example, the presence or absence of degradation, or a degradation level, of a semiconductor element). In this arrangement, the degradation diagnosis device 40 can transmit the diagnosis result to the user interface 72, via the insulation 63 without using a high-resolution device such as an isolated AD converter.

Although the embodiments are described above, the above embodiments are presented as examples, and the present disclosure is not limited to the above embodiments. The above embodiments can be embodied in various other forms, and various combinations, omissions, substitutions, changes, and the like can be made without departing from the gist of the present disclosure. These embodiments and modifications are within the scope and gist of the present disclosure. The claims and their equivalents are intended to cover such forms or modifications as would fall within the scope and gist of the disclosure.

For example, the gate resistance 21 may be provided in the push-pull circuit 10. The gate resistance 21 provided in push-pull circuit 10 may be a resistance (turn-off gate resistance) that is inserted in series in the second switch 12 in a signal path between the connection point 14 and the second power line 16. In this case, the speed-up capacitor circuit 30 is connected in parallel to the turn-off gate resistance. In the diode 33 in speed-up capacitor circuit 30, an anode is connected to a gate drive line between the turn-off gate resistance and the gate G, and a cathode is connected to one end of each of the capacitor 31 and the discharge resistor 32.

The operation and effect in the configuration where the gate resistance 21 serves as the turn-off gate resistance are the same as the operation and effect in the above-described embodiments where the gate resistance 21 is inserted in series between the connection point 14 and gate G. The description of the operation and effect is omitted by referring to the above description.

The gate resistance 21 provided in push-pull circuit 10 may be a resistance (turn-on gate resistance) inserted in series with the first switch 11 in a signal path between the connection point 14 and the first power line 15. In this case, the speed-up capacitor circuit 30 is connected in parallel to the turn-on gate resistance. A cathode of the diode 33 in the speed-up capacitor circuit 30 is connected to a gate drive line between the turn-on gate resistance and the gate G, and an anode is connected to one end of each of the capacitor 31 and the discharge resistor 32.

In the configuration where the gate resistance 21 is a turn-on gate resistance, when the first switch 11 switches from off to on, the charge from the first power line 15 moves to the gate G of the semiconductor element 1 through the diode 33. As a result, the voltage Vgs between the gate G and the source S of the semiconductor element 1 quickly rises, and thus the turn-on time of the semiconductor element 1 is reduced. As the voltage Vgs of the semiconductor element 1 rises, the voltage (capacitor voltage Vc) generated across the capacitor 31 rises. When the capacitor voltage Vc becomes equal to the voltage Vgs, the charge accumulated in the capacitor 31 starts to discharge through the discharge resistor 32. Thus, even if the turn-on time of the semiconductor element 1 is reduced, the discharge of the capacitor 31 can be started during the turn-on process of the semiconductor element 1.

Even when the gate resistance 21 is a turn-on gate resistance, the voltage value when the capacitor voltage Vc becomes equal to the voltage Vgs differs before and after the degradation of the semiconductor element 1, as in the case shown in FIG. 3. The degradation diagnosis device 40 diagnoses the degradation of the semiconductor element 1 by observing a difference between the voltage value V1 and the voltage value V2. For example, the degradation diagnosis device 40 diagnoses that the semiconductor element 1 is degraded when the magnitude of the capacitor voltage Vc detected during the switching operation of the semiconductor element 1 (in this example, during turn-on,) is greater than the voltage value V2 that is set as the decision threshold.

What is claimed is:

1. A degradation diagnosis system comprising:
a semiconductor element including
a gate,
a first main terminal that is a source or an emitter, and
a second main terminal that is a drain or a collector;
a push-pull circuit;
a gate resistance provided in the push-pull circuit or between the push-pull circuit and the gate;
a capacitor coupled in parallel with the gate resistance; and
a degradation diagnosis device configured to diagnose degradation of the semiconductor element based on a capacitor voltage that is generated across the capacitor.

2. The degradation diagnosis system according to claim 1, wherein the degradation diagnosis device is configured to diagnose the degradation of the semiconductor element based on a voltage value, in a case where the capacitor voltage is equal to a voltage between the gate and the first main terminal.

3. The degradation diagnosis system according to claim 2, wherein the voltage value is a maximum value of the capacitor voltage.

4. The degradation diagnosis system according to claim 3, further comprising:
a peak hold circuit configured to hold the maximum value of the capacitor voltage during a predetermined time period,
wherein the voltage value is the maximum value held by the peak hold circuit.

5. The degradation diagnosis system according to claim 4, wherein the peak hold circuit is configured to sample the maximum value in an operating cycle of the semiconductor element.

6. The degradation diagnosis system according to claim 5, wherein the operating cycle is a zero-crossing period of an output voltage or an output current of the semiconductor element.

7. The degradation diagnosis system according to claim 5, wherein the operating cycle is a carrier cycle of the semiconductor element.

8. The degradation diagnosis system according to claim 1, wherein the degradation diagnosis device is configured to diagnose the degradation of the semiconductor element based on the capacitor voltage and information related to the semiconductor element.

9. The degradation diagnosis system according to claim 8, wherein the degradation diagnosis device is configured to diagnose the degradation of the semiconductor element, upon occurrence of a condition in which the information related to the semiconductor element satisfies a predetermined condition.

10. The degradation diagnosis system according to claim 8, wherein the degradation diagnosis device is configured to diagnose the degradation of the semiconductor element, by comparing the capacitor voltage with a threshold that is set based on the information related to the semiconductor element.

11. The degradation diagnosis system according to claim 8, wherein the degradation diagnosis device is configured to diagnose the degradation of the semiconductor element based on the information related to the semiconductor element, upon occurrence of a condition in which the capacitor voltage is greater than a constant threshold.

12. The degradation diagnosis system according to claim 8, wherein the degradation diagnosis device is configured to diagnose the degradation of the semiconductor element, upon occurrence of a condition in which the information related to the semiconductor element satisfies a predetermined condition, in conjunction with a condition in which the capacitor voltage is greater than a constant threshold.

13. A degradation diagnosis method comprising:
diagnosing degradation of a semiconductor element based on a capacitor voltage that is generated across a capacitor, the capacitor being coupled in parallel with a gate resistance, and the gate resistance being provided in a push-pull circuit or between a push-pull circuit and a gate of the semiconductor element.

14. A power converter comprising:
a semiconductor element including
a gate,
a first main terminal that is a source or an emitter, and
a second main terminal that is a drain or a collector;
a push-pull circuit;
a gate resistance provided in the push-pull circuit or between the push-pull circuit and the gate;
a capacitor coupled in parallel with the gate resistance;
a degradation diagnosis device configured to diagnose degradation of the semiconductor element based on a capacitor voltage that is generated across the capacitor; and
a peak hold circuit configured to hold a maximum value of the capacitor voltage during a predetermined time period, in an operating cycle of the semiconductor element.

15. The power converter according to claim 14, wherein the operating cycle is a zero-crossing period of an output voltage or an output current of the semiconductor element.
